(19) United States
(12) Patent Application Publication
(10) Pub. No.: US 2016/0066467 A1
(43) Pub. Date: Mar. 3, 2016

(54) HVAC CONTROL UNIT AND WALL PLATE MODULE

(71) Applicant: Carrier Corporation, Farmington, IN (US)

(72) Inventors: Thomas E. Lindley, Fort Wayne, IN (US); Brian Eicher, Fort Wayne, IN (US)

(21) Appl. No.: 14/822,259

(22) Filed: Aug. 10, 2015

Related U.S. Application Data
(60) Provisional application No. 62/042,062, filed on Aug. 26, 2014.

(51) Int. Cl. H05K 7/14; H05K 1/11

(52) U.S. Cl. CPC H05K 7/1427; H05K 1/111; H05K 2201/10742

(57) ABSTRACT

A HVAC controller system including a control unit including a first connection device and a wall plate module, including a wall plate board assembly and second connection device disposed on the wall plate board assembly, wherein when the control unit and wall plate module are engaged with one another, the first connection device and the second connection device are in contact with one another.

### CROSS REFERENCE TO RELATED APPLICATIONS

The present application is related to, and claims the priority benefit of, U.S. Provisional Patent Application Ser. No. 62/042,062 filed Aug. 26, 2014, the contents of which are hereby incorporated in their entirety into the present disclosure.

### TECHNICAL FIELD OF THE DISCLOSED EMBODIMENTS

The presently disclosed embodiments generally relate to heating, ventilation, and air-conditioning (“HVAC”) systems, and more particularly, to a HVAC control unit and wall plate module.

### BACKGROUND OF THE DISCLOSED EMBODIMENTS

A typical HVAC controller (i.e. thermostat) lacks commercial appeal due to the bulky block size. The bulky size may be attributed to the necessary spacing on the HVAC controller's control board, and the mechanical means for mounting. This extra spacing and mechanical mounting increases cost to the HVAC controller. There is therefore a need for a more cost effective HVAC controller that is less bulky in size.

### SUMMARY OF THE DISCLOSED EMBODIMENTS

In one aspect, an HVAC controller system is provided. The HVAC controller system includes a control unit configured to control at least one HVAC component. In one embodiment, the control unit includes a thermostat. The HVAC controller system further includes a wall plate module configured to engage and hold the control unit.

The control unit includes a control unit housing. The control unit housing further includes a first housing side, a second housing side, and a housing aperture disposed therethrough. The control unit further includes a control unit board assembly disposed on the first housing side of the control unit housing. The control unit board assembly is populated with a plurality of electronic components in electrical communication with each other to perform the necessary functions to allow the control unit to control the at least one HVAC component.

The control unit board assembly further includes a first control board side a second control board side, and a first connection device such that the first connection device may be accessed from the second housing side of the control unit housing through the housing aperture. The first connection device is in electrical communication with at least one of the plurality of electrical components to send and receive electrical signals between the control unit and the at least one HVAC component. In one embodiment the first connection device may include at least one connectivity pad. In another embodiment, the first connection device may include at least one connector pin. In one embodiment, the at least one connector pin includes a compression pin.

In one embodiment, the control unit housing further includes at least one protrusion disposed thereon. The at least one protrusion is configured to engage the wall plate module to securely couple the control unit to the wall plate module.

The wall plate module includes a wall plate housing, including a first plate side, a second plate side, and a first plate aperture disposed therethrough. The wall plate module further includes a wall plate board assembly disposed in the first plate aperture. In one embodiment, the wall plate housing further includes at least one second wall plate aperture disposed therein.

The wall plate board assembly further includes a first wall plate board side, a second wall plate board side, and a second connection device disposed on the second wall plate board side such that the second connection device is accessible through the first plate aperture.

In one embodiment the second connection device may include at least one connectivity pad. In another embodiment, the second connection device may include at least one connector pin. In one embodiment, the at least one connector pin includes a compression pin. The wall plate board assembly further includes a third connection device, disposed on the second plate board side, in electrical communication with the second connection device.

Other embodiments are also disclosed.

### BRIEF DESCRIPTION OF THE DRAWINGS

The embodiments and other features, advantages and disclosures contained herein, and the manner of attaining them, will become apparent and the present disclosure will be better understood by reference to the following description of various exemplary embodiments of the present disclosure taken in conjunction with the accompanying drawings, wherein:

FIG.1 includes perspective views of an HVAC controller unit and a wall plate module.

### DETAILED DESCRIPTION OF THE DISCLOSED EMBODIMENTS

For the purposes of promoting an understanding of the principles of the present disclosure, reference will now be made to the embodiments illustrated in the drawings, and specific language will be used to describe the same. It will nevertheless be understood that no limitation of the scope of this disclosure is thereby intended.

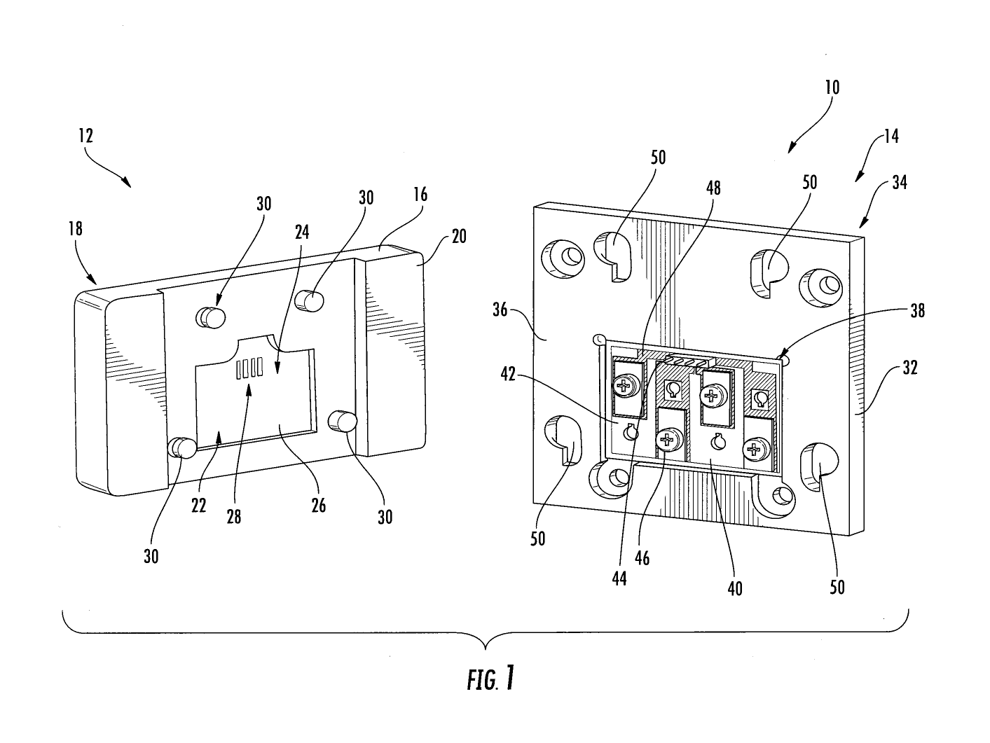

FIG. 1 illustrates an HVAC controller system generally indicated at 10. The HVAC controller system 10 includes a control unit 12 configured to control at least one HVAC component (not shown). In one embodiment, the control unit 12 includes a thermostat. It will be appreciated that the control unit may control other functions, such as humidity to name one non-limiting example. The HVAC controller system 10 further includes a wall plate module 14 configured to engage and hold the control unit 12.

The control unit 12 includes a control unit housing 16. The control unit housing 16 further includes a first housing side 18, a second housing side 20, and a housing aperture 22 disposed therethrough. The control unit 12 further includes a control unit board assembly 24 disposed on the first housing side 18 of the control unit housing 16. It will be appreciated that the control unit 12 may also include a display device (not shown), such as a liquid crystal display LCD to name one non-limiting examples, in electrical communication with the control unit board assembly 24. It will also be appreciated that the control unit board assembly 24 may be coupled to the first housing side 18 by any acceptable means, for example, posts, clips, inset, and glue to name a few non-limiting examples. The control unit board assembly 24 is populated with a plurality of electronic components (e.g. memory, processor and power supply to name a few non-limiting examples) in electrical communication with each other to perform the necessary functions to allow the control unit 12 to control the at least one HVAC component.

The control unit board assembly 24 further includes a first control board side (not shown), a second control board side 26, and a first connection device 28 such that the first connection device 28 may be accessed from the second housing side 20 of the control unit housing 16 through the housing aperture 22. The first connection device 28 is in electrical communication with at least one of the plurality of electrical components to send and receive electrical signals between the control unit 12 and the at least one HVAC component. In one embodiment the first connection device 28 may include at least one connectivity pad. In another embodiment, the first connection device 28 may include at least one connector pin. In one embodiment, the at least one connector pin includes a compression pin. In the example shown, the first connection device 28 consists of four connectivity pads. It will be appreciated that there may be more or fewer than four connectivity pads.

In one embodiment, the control unit housing 16 further includes at least one protrusion 30 disposed thereon. The at least one protrusion 30 is configured to engage the wall plate module 14 (later described herein) to securely couple the control unit 12 to the wall plate module 14. In the example shown, four protrusions 30 are disposed on the second housing side 20 of the control unit housing 16. It will be appreciated that more or fewer than four protrusions 30 may be used. It will also be appreciated that the at least one protrusion 30 may be placed in any desired location to enable coupling with a wall plate module 14.

The wall plate module 14 includes a wall plate housing 32, including a first plate side 34, a second plate side 36, and a first plate aperture 38 disposed therethrough. The wall plate module 14 further includes a wall plate board assembly 40 disposed in the first plate aperture 38. It will be appreciated that the wall plate board assembly 40 may be disposed within the first plate aperture 38 by any acceptable means, for example, posts, clips, inset, and glue to name a few non-limiting examples.

The wall plate board assembly 40 further includes a first wall plate board side (not shown), a second wall plate board side 42, and a second connection device 44 disposed on the second wall plate board side 42 such that the second connection device 44 is accessible through the first plate aperture 38. In one embodiment the second connection device 44 may include at least one connectivity pad. In another embodiment, the second connection device 44 may include at least one connector pin. In one embodiment, the at least one connector pin includes a compression pin. For example, a compression pin includes a pin, tube, and spring, such as a spring loaded contact connector to name one non-limiting example, wherein the pin may be compressed within the tube by applying pressure thereon.

The wall plate board assembly 40 further includes a third connection device 46, disposed on the second plate board side 42, in electrical communication with the second connection device 44. It will be appreciated that wiring from the at least one HVAC component is connected to the third connection device 46 to transmit electrical signals between the at least one HVAC component and the HVAC controller system 10 when the control unit 12 is coupled to the wall plate module 14. For example, third connection device 46 is configured to transmit electrical signals between the second connection device 44 via a connection path 48. It will be appreciated that the third connection device 46 may be any connection device enabled to hold electrical wiring, such as a terminal block and metal plates to name a couple of non-limiting examples.

In one embodiment, the wall plate housing 32 further includes at least one second wall plate aperture 50 disposed therein. The at least one second wall plate aperture 50 is configured to engage and mate with the at least one protrusion 30 from the control unit housing 16 to securely fasten the control unit 12 to the wall plate module 14.

As the control unit 12 and wall plate module 14 engage with one another, second connection device 44 comes into contact with the first connection device 28. For example, each of the connector pins on the wall plate module 14 come into contact with each of the respective connectivity pads on the control unit 12. The connector pins are then able to transfer the electrical signals from the third connection device 46 to the control unit 12 via the connection between the connector pins and the connectivity pads.

It will therefore be appreciated that the present embodiments provide improvements in the HVAC controller system 10. The protrusions 30 and second wall plate apertures 50 allow for the removal of additional locking and mating mechanisms; thus reducing the costs of the HVAC controller system 10. The first connection device 28 and the second connection device 44 allow for small connections; thus, reducing the size of board layouts that have an overall impact on the size of the HVAC controller system 10.

While the invention has been illustrated and described in detail in the drawings and foregoing description, the same is to be considered as illustrative and not restrictive in character, it being understood that only certain embodiments have been shown and described and that all changes and modifications that come within the spirit of the invention are desired to be protected.

What is claimed is:

1. An HVAC controller system comprising:
a control unit comprising:
a control unit housing including a first housing side, a second housing side, and a housing aperture disposed therethrough;
a control board assembly, including a first control board side and a second control board side, wherein the second control board side is coupled to the first housing side of the control unit housing; and
a first connection device disposed on the second control board side;
wherein the first connection device is accessible from the second housing side through the housing aperture.

2. The HVAC controller system of claim 1 further comprising
a wall plate module comprising
a wall plate housing including a first plate housing side, a second plate housing side, and a plate aperture disposed therethrough;
a wall plate board assembly, including a first plate board side and a second plate board side, wherein the second plate board side is coupled to the second plate housing side; and
a second connection device disposed on the second plate board side;
wherein the second connection device is accessible from the second plate housing side; wherein the control unit and the wall plate module are engaged such that the first connection device is in contact with the second connection device.

3. The HVAC controller system of claim 1, wherein the first connection device is selected from the group consisting of: at least one connectivity pad and at least one connector pin.

4. The HVAC controller system of claim 3, wherein the second connection device is selected from the group consisting of: at least one connectivity pad and at least one connector pin.

5. The HVAC controller system of claim 4, wherein the at least one connector pin comprises a compression pin.

6. The HVAC controller system of claim 1, wherein the wall plate board assembly further comprises a third connection device disposed on the second plate board side, wherein the third connection device is in electrical communication with the second connection device.

7. The HVAC controller system of claim 1, wherein the wall plate housing further comprises at least one aperture disposed thereon.

8. The HVAC controller system of claim 1, wherein the control unit housing further comprises at least one protrusion disposed thereon.

9. The HVAC controller system of claim 1, wherein the first connection device is in electrical communication with at least one of a plurality of electronic components disposed on the control unit board assembly.

10. A HVAC control mounting assembly comprising:
a housing including a first housing side, a second housing side, and a first housing aperture disposed therethrough;
a board assembly including a first board side and a second board side, wherein the second board side is coupled to the second housing side, and
a first connection device disposed on the second plate board side;
wherein the first connection device is selected from the group consisting of: at least one connectivity pad and at least one connector pin.

11. The HVAC control mounting assembly of claim 10, wherein the at least one connector pin comprises a compression pin.

12. The HVAC control mounting assembly of claim 10, wherein the board assembly further comprises a second connection device, wherein the first connection device is in electrical communication with the second connection device.

13. The HVAC control mounting assembly of claim 10, wherein the housing further comprises at least one second housing aperture disposed thereon.

14. An HVAC controller comprising:
a housing including a first housing side, a second housing side, and a housing aperture disposed therethrough;
a board assembly, including a first board side and a second board side, wherein the second board side is coupled to the second housing side; and
a connection device disposed on the second control board side, wherein the connection device is accessible from the second housing side through the housing aperture.

15. The HVAC controller of claim 14, wherein the connection device is selected from the group consisting of: at least one connectivity pad and at least one connector pin.

16. The HVAC controller of claim 15, wherein the at least one connector pin comprises a compression pin.

17. The HVAC controller of claim 14, wherein the housing further comprises at least one protrusion disposed thereon.

18. The HVAC controller of claim 14, wherein the connection device is in electrical communication with at least one of a plurality of electronic components disposed on the board assembly.
